(19) United States
(12) Patent Application Publication
(10) Pub. No.: US 2010/0103199 A1
(43) Pub. Date: Apr. 29, 2010

(54) DRIVING APPARATUS

(75) Inventor: Chao-An Chen, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NOVATEK MICROELECTRONICS CORP., Hsinchu (TW)

(21) Appl. No.: 12/335,548

(22) Filed: Dec. 16, 2008

(30) Foreign Application Priority Data
Oct. 28, 2008 (TW) 97141460

(51) Int. Cl. G09G 5/10; H03M 1/66

(52) U.S. Cl. 345/690; 341/144

(57) ABSTRACT

A driving apparatus used for a display is disclosed. The driving apparatus includes a voltage divider, a first and a second digital to analog converter, and a first voltage amplifier. The voltage divider divides a first voltage to generate a positive polarity gamma voltage and a negative polarity gamma voltage. The first digital to analog converter converts a first gray level signal to a first analog gray level signal. The second digital to analog converter converts a second gray level signal to a second analog gray level signal. The first voltage amplifier receives one of the first or the second analog gray level signal. Wherein, the voltage divider, the first and the second digital to analog converters receive a first voltage as an operating voltage, and the first voltage amplifier receives a second voltage as an operating voltage. Moreover, the second voltage is larger than the first voltage.

### CROSS-REFERENCE TO RELATED APPLICATION

This application claims the priority benefit of Taiwan application serial no. 97141460, filed on Oct. 28, 2008. The entirety of the above-mentioned patent application is hereby incorporated by reference herein and made a part of this specification.

### BACKGROUND OF THE INVENTION

1. Field of the Invention

The present invention relates to a driving apparatus. More particularly, the present invention relates to a driving apparatus used for driving a display.

2. Description of Related Art

With development of electronics technology, a plenty of multimedia devices having an audio-video playing function is accordingly developed. While simultaneously considering an image quality, a product cost and a selling price, a plurality of driving methods and circuits of displays are developed. The displays include commonly used liquid crystal displays (LCD), light emitting diodes (LED) and vacuum fluorescent displays (VFD), etc.

However, regardless whatever the display is, when a driver thereof drives a corresponding display panel, a driving voltage with a relatively high voltage level has to be provided. Generally, the driving voltage is much higher than a logical voltage required by a logical circuit for data operation. FIG. 1 is a schematic diagram of a conventional driving apparatus. The driving apparatus 100 stores gray levels of pixels to be displayed into latches 141 and 142 in form of digital signals. When a gray level signal is applied to turn on a corresponding pixel of the display, the gray level signal is converted into a high voltage (or a negative high voltage) signal that can drive the display by digital to analog converters 121 and 122 according to gamma voltage signals VGMA1 and VGMA2 provided by a voltage divider 110.

Therefore, to accomplish the above voltage conversion operation, the conventional driver generally applies so-called voltage level shifters 131 and 132 to convert the gray level signal from a low voltage to a high voltage. For a single-stage voltage level shifter 131 or 132, a circuit area thereof is not great, though a driver generally has a plurality of driving channels, and each of the driving channels requires a plurality of voltage level shifters. In other words, a quantity of the voltage level shifters within the driver is huge, so that the circuit area and cost thereof are greatly increased.

Moreover, to construct an output stage in the driver to drive the display, a plurality of high voltage electronic devices is required. For example, the voltage divider 110, the voltage level shift circuits 131-132, the digital to analog converters 121-122, an interleaver 151 and amplifiers 161-162 within the driving apparatus 100 are all high voltage electronic devices. Theses high voltage electronic devices may occupy a relatively great circuit area during fabrication of integrated circuits (IC). Similarly, the circuit area and the cost of the driver are increased.

### SUMMARY OF THE INVENTION

The present invention is directed to a driving apparatus, by which not only utilization of high voltage devices is decreased, but also utilization of boost voltage level shifters is unnecessary, so as to save a circuit area and reduce a cost thereof.

The present invention provides a driving apparatus used for a display. The driving apparatus includes a voltage divider, a first and a second digital to analog converter, and a first voltage amplifier. The voltage divider divides a first voltage to generate a positive polarity gamma voltage and a negative polarity gamma voltage. The first digital to analog converter is coupled to the voltage divider, and converts a first gray level signal to a first analog gray level signal according to the positive polarity gamma voltage. The second digital to analog converter is also coupled to the voltage divider, and converts a second gray level signal to a second analog gray level signal according to the negative polarity gamma voltage. The first voltage amplifier is coupled to the first and the second digital to analog converter, and receives one of the first or the second analog gray level signal. Wherein, the voltage divider, the first and the second digital to analog converters receive the first voltage as an operating voltage, and the first voltage amplifier receives a second voltage as an operating voltage. Moreover, the second voltage is greater than the first voltage.

In an embodiment of the present invention, the second voltage is N times greater than the first voltage, wherein N is greater than 1.

In an embodiment of the present invention, the first voltage amplifier amplifies one of the first and the second analog gray level signal for N times.

In an embodiment of the present invention, the first voltage amplifier includes a first amplifier, a first transistor, a second transistor, a first voltage-dividing impedance device and a second voltage-dividing impedance device. The first amplifier has a first input terminal, a second input terminal and an output terminal, wherein the first input terminal receives one of the first and the second analog gray level signal. The first transistor has a gate, a first source/drain and a second source/drain, wherein the gate is coupled to the output terminal of the first amplifier, and the first source/drain is coupled to the second voltage. The second transistor also has a gate, a first source/drain and a second source/drain, wherein the gate is coupled to the output terminal of the first amplifier, the first source/drain is coupled to the second source/drain of the first transistor, and the second source/drain is coupled to a ground voltage. One terminal of the first voltage-dividing impedance device is coupled to the second source/drain of the first transistor, and another terminal thereof is coupled to the second input terminal of the first amplifier. Moreover, the second voltage-dividing impedance device is coupled in serial between the first voltage-dividing impedance device and the ground voltage.

In an embodiment of the present invention, the first transistor is a P channel metal oxide semiconductor field effect transistor (MOSFET) (PMOS).

In an embodiment of the present invention, the second transistor is a N channel MOSFET (NMOS).

In an embodiment of the present invention, the driving apparatus further includes an interleaver and a second voltage amplifier. The interleaver is coupled between coupling paths between the first and the second digital to analog converter and the first voltage amplifier. The second voltage amplifier is coupled to the interleaver, and is used for receiving and amplifying one of the first and the second analog gray level signal. Wherein, the interleaver transmits the digital positive polarity gamma voltage to one of the first voltage amplifier and the second voltage amplifier, and transmits the digital negative polarity gamma voltage to another one of the first voltage amplifier and the second voltage amplifier according to a polarity control signal.

In an embodiment of the present invention, the second voltage amplifier includes a second amplifier, a third transistor, a fourth transistor, a third voltage-dividing impedance device and a fourth voltage-dividing impedance device. The second amplifier has a first input terminal, a second input terminal and an output terminal, wherein the first input terminal receives one of the first and the second analog gray level signal. The third transistor has a gate, a first source/drain and a second source/drain, wherein the gate is coupled to the output terminal of the second amplifier, and the first source/drain is coupled to the second voltage. The fourth transistor also has a gate, a first source/drain and a second source/drain, wherein the gate is coupled to the output terminal of the second amplifier, the first source/drain is coupled to the second source/drain of the third transistor, and the second source/drain is coupled to the ground voltage. One terminal of the third voltage-dividing impedance device is coupled to the second source/drain of the third transistor, and another terminal thereof is coupled to the second input terminal of the second amplifier. Moreover, the fourth voltage-dividing impedance device is coupled in serial between the third voltage-dividing impedance device and the ground voltage.

In an embodiment of the present invention, the third transistor is a PMOS.

In an embodiment of the present invention, the second transistor is a NMOS.

In an embodiment of the present invention, the driving apparatus further includes a first data storage device and a second data storage device. The first data storage device is coupled to the first digital to analog converter, and is used for providing the first gray level signal. The second data storage device is coupled to the second digital to analog converter, and is used for providing the second gray level signal.

In an embodiment of the present invention, the first and the second data storage device are latches or flip-flops.

In an embodiment of the present invention, the voltage divider includes a plurality of impedance devices coupled in serial between the first voltage and the ground voltage.

In an embodiment of the present invention, the resistors are formed by N channel/P channel wells or a polysilicon layer.

In the present invention, a voltage level of the gamma voltage is first decreased, and then a driving voltage to be transmitted to a display is increased by a voltage amplifier at an output terminal of the driving apparatus. Therefore, the circuit of the driving apparatus is mostly operated under a relatively low operating voltage, and utilization of the high voltage devices corresponding to the circuit devices is unnecessary, so that an area size of the circuit can be effectively saved. Moreover, since the voltage level is increased by the voltage amplifier, utilization of boost voltage level shifters is unnecessary, which can also save the area size of the circuit.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of a conventional driving apparatus.

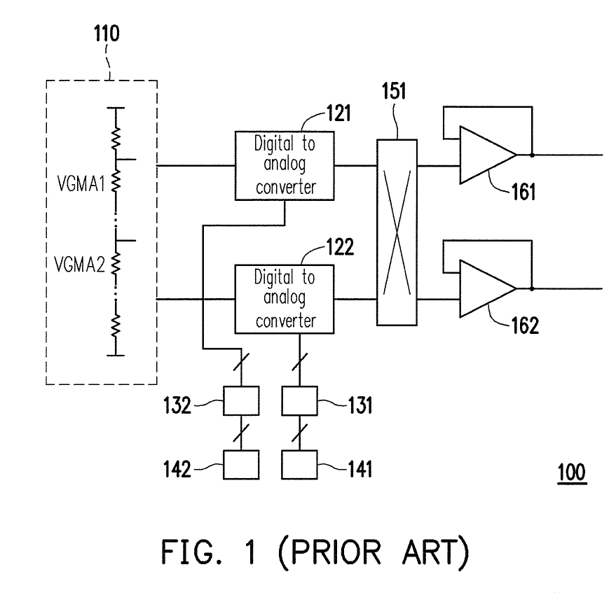

FIG. 2 is a schematic diagram illustrating a driving apparatus 200 according to an embodiment of the present invention.

FIG. 3 is a schematic diagram illustrating a driving apparatus 300 according to another embodiment of the present invention.

FIG. 4 is a circuit diagram illustrating a voltage amplifier according to an embodiment of the present invention.

### DESCRIPTION OF EMBODIMENTS

To fully convey the concept of the present invention, embodiments are provided below with reference of figures for describing the driving apparatus of the present invention in detail.

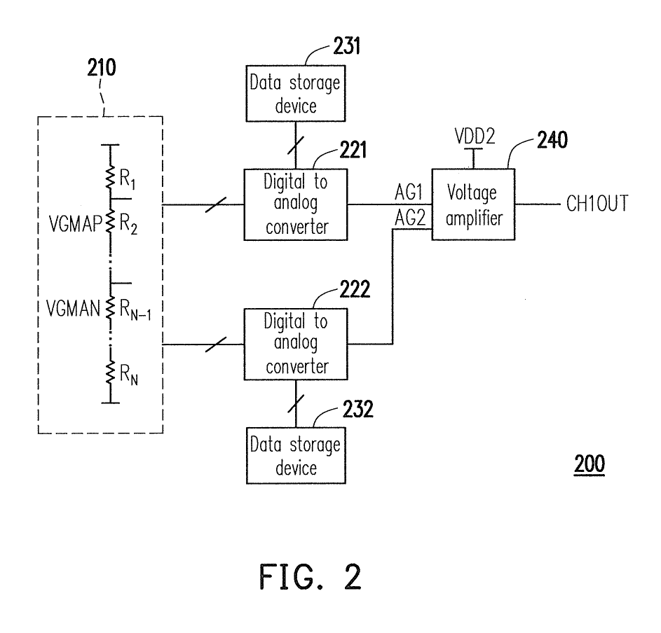

Referring to FIG. 2 first, FIG. 2 is a schematic diagram illustrating a driving apparatus 200 according to an embodiment of the present invention. The driving apparatus 200 includes a voltage divider 210, digital to analog converters 221-222, data storage devices 231-232 and a voltage amplifier 240. The voltage divider 210 is formed by a plurality of serially connected impedance devices R₁-R_{N}, wherein the impedance devices R₁-R_{N} are coupled between a voltage VDD1 and a ground voltage GNDA in serial, and divide the voltage VDD1 into a positive polarity gamma voltage VGMAP and a negative polarity gamma voltage VGMAN. It should be noted that the positive polarity gamma voltage VGMAP or the negative polarity gamma voltage VGMAN does not refer to a single voltage value, but refers to one or more values of the positive polarity gamma voltage VGMAP or the negative polarity gamma voltage VGMAN generated according to different features of the displays to be driven.

In the present embodiment, the voltage VDD1 received by the voltage divider 210 is a relatively low voltage, i.e. a logical voltage level. In other words, the positive polarity gamma voltage VGMAP or the negative polarity gamma voltage VGMAN divided by the voltage divider 210 is not greater than the logical voltage level VDD1. Therefore, all of the impedance devices R₁-R_{N} of the voltage divider 210 can be formed by low voltage devices, for example, low voltage resistors. When the driving apparatus 200 is constructed on a chip, the low voltage resistors can be formed by low voltage N channel or P channel wells or a low voltage polysilicon layer. The above method of forming the resistor by the low voltage N channel or P channel wells or the low voltage polysilicon layer is known by those skilled in the art, and therefore detailed description thereof is not repeated.

Moreover, the driving apparatus 200 stores gray level data to be displayed on a display into the data storage devices 231 and 232. The data storage devices 231 and 232 does not respectively represent only one bit, and a bit number of the data storage device 231 or 232 is determined according to a displayed gray level supported by the driving apparatus 200. For example, an 8 bits gray level (256 gray level) requires an 8 bits data storage device 231 or 232. Here, the data storage devices 231 and 232 are generally formed by standard logical cells, for example, latches or flip-flops. In other words, the data storage devices 231 and 232 also work under the low level logical voltage, for example, the voltage VDD1.

The digital to analog converters 221 and 222 are coupled to the voltage divider 210, and receive the positive polarity gamma voltage VGMAP and the negative polarity gamma voltage VGMAN generated by the voltage divider 210. Moreover, the digital to analog converters 221 and 222 are respectively coupled to the data storage devices 231 and 232, and respectively receive the gray level data stored in the data storage devices 231 and 232. Wherein, the digital to analog converter 221 converts the received gray level data, and generates an analog gray level signal AG1 according to the positive polarity gamma voltage VGMAP. Similarly, the digital to analog converter 222 converts the received gray level data, and generates an analog gray level signal AG2 according to the negative polarity gamma voltage VGMAN.

Since the signals received by the digital to analog converters 221 and 222 are all low voltage (not greater than the voltage VDD1) signals, the operating voltage required by the digital to analog converters 221 and 222 can be the low voltage as VDD1.

The voltage amplifier 240 is coupled to the digital to analog converters 221 and 222, and receives the analog gray signals AG1 and AG2. The voltage amplifier 240 receives and amplifies one of the analog gray signals AG1 and AG2 to provide a driving voltage CH1OUT to the display for driving the display. Since the display requires a relatively high voltage, the voltage amplifier used for generating relatively high driving voltage CH1OUT requires a relatively high operating voltage, for example, a voltage VDD2. Namely, the voltage VDD2 is greater than the voltage VDD1.

Next, an actual example is provided in allusion to states of operating voltages used by elements within the driving apparatus 200. When the logical voltage is 3.3V, the voltage VDD1=3.3V. When the voltage required for driving the display is 13.2V, the voltage VDD2=13.2V, wherein a ratio between the voltage VDD2 and the voltage VDD1 is 4:1. Now, the positive/negative polarity gamma voltage generated by the voltage divider 210 can provide a quarter of the voltage required by the display, so that the voltage amplifier 240 has to amplify the received analog gray level signal AG1 or AG2 for four times.

It should be noted that in the driving apparatus 200, only the voltage amplifier 240 requires the voltage VDD2 to serve as the operating voltage. Namely, besides the voltage amplifier 240, all of the elements within the driving apparatus 200 can be electronic devices applying the low voltage, by which a circuit area thereof is effectively saved.

In the following content, another embodiment is provided to further describe the present invention.

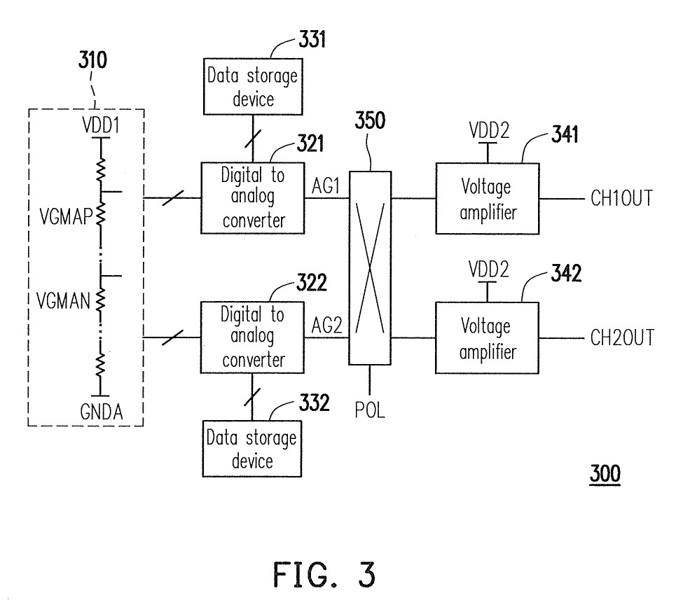

Referring to FIG. 3, FIG. 3 is a schematic diagram illustrating a driving apparatus 300 according to another embodiment of the present invention. The driving apparatus 300 includes a voltage divider 310, digital to analog converters 321-322, data storage devices 331-332, an interleaver 350 and voltage amplifiers 341-342. In the present embodiment, the driving apparatus 300 can provide two channels for driving the display (not shown). Therefore, different to the aforementioned embodiment, the driving apparatus 300 applies the interleaver 350 and two voltage amplifiers 341 and 342. The interleaver 350 distributes the analog gray level signals AG1 and AG2 generated by the digital to analog converters 321-322 to the voltage amplifiers 341 and 342 according to a polarity control signal POL. Namely, when the voltage amplifier 341 is assigned to receive the analog gray level signal AG1, the voltage amplifier 342 is assigned to receive the analog gray level signal AG2. Comparatively, when the voltage amplifier 341 is assigned to receive the analog gray level signal AG2, the voltage amplifier 342 is assigned to receive the analog gray level signal AG1.

Distribution of the gray level signals AG1 and AG2 is used to implement a so-called dot inversion, line inversion or column inversion technique within the LCD, for example, when the driving voltages CH1OUT and CH2OUT output from the voltage amplifiers 341 and 342 are provided to different lines, the line inversion is implemented. When the driving voltages CH1OUT and CH2OUT output from the voltage amplifiers 341 and 342 are provided to different columns, the column inversion is implemented.

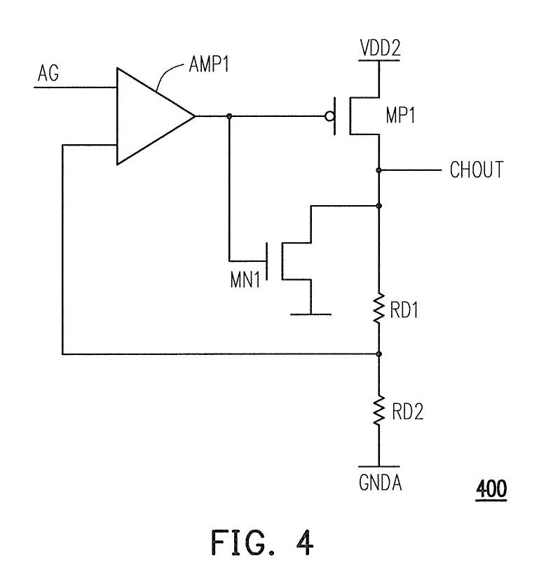

Referring to FIG. 4 for the implementing method of the voltage amplifiers 240, 341 and 342 of the driving apparatus 200 and 300, FIG. 4 is a circuit diagram illustrating a voltage amplifier according to an embodiment of the present invention. The voltage amplifier 400 includes an amplifier AMP1, transistors MP1, MN1, a voltage-dividing impedance device RD1 and a voltage-dividing impedance device RD2. A first input terminal of the amplifier AMP1 receives an analog gray level signal AG. A gate of the transistor MP1 is coupled to an output terminal of the amplifier AMP1, and a first source/drain thereof is coupled to the voltage VDD2. A gate of the transistor MN1 is coupled to the output terminal of the amplifier AMP1, a first source/drain thereof is coupled to a second source/drain of the transistor MP1 and generates a driving voltage CHOUT, and a second source/drain thereof is coupled to the ground voltage GNDA. A first terminal of the voltage-dividing impedance device RD1 is coupled to the second source/drain of the transistor MP1, another terminal thereof is coupled a second input terminal of the amplifier AMP1. The voltage-dividing impedance device RD2 is serially connected between the voltage-dividing impedance device RD1 and the ground voltage GNDA. The transistor MP1 is a PMOS, and the transistor MN1 is a NMOS.

Under such a structure, a differential pair in the amplifier AMP1 can be a P-type differential pair rather than a so-called rail to rail differential pair. The P-type differential pair can be an electronic device only requiring a middle voltage instead of an electronic device requiring the high voltage.

Moreover, the voltage-dividing impedance device RD1 and the voltage-dividing impedance device RD2 are used for adjusting an amplification of the voltage amplifier 400, and when the amplification of the voltage amplifier 400 is N, a ratio between resistances of the voltage-dividing impedance device RD1 and the voltage-dividing impedance device RD2 is N−1:N.

In summary, digital to analog conversion of the gray level signal is performed based on relatively low gamma voltage, and the voltage amplifier is used only at a last stage of the driving apparatus to generate the driving voltage. Therefore, elements require the high operating voltage can be effectively reduced, and not only utilization of the voltage level shifters is unnecessary, but also utilization of high voltage electronic devices is effectively reduced, so that the circuit area and the production cost can be effectively reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A driving apparatus, adapted to a display, comprising:
a voltage divider, for dividing a first voltage to generate a positive polarity gamma voltage and a negative polarity gamma voltage;
a first digital to analog converter, coupled to the voltage divider, for converting a first gray level signal to a first analog gray level signal according to the positive polarity gamma voltage;
a second digital to analog converter, coupled to the voltage divider, for converting a second gray level signal to a second analog gray level signal according to the negative polarity gamma voltage; and
a first voltage amplifier, coupled to the first and the second digital to analog converter, for receiving and amplifying one of the first or the second analog gray level signal,
wherein the voltage divider, the first and the second digital to analog converters receive the first voltage as operating voltage, the first voltage amplifier receives a second voltage as operating voltage, and the second voltage is greater than the first voltage.

2. The driving apparatus as claimed in claim 1, wherein the second voltage is N times of the first voltage, wherein N is greater than 1.

3. The driving apparatus as claimed in claim 2, wherein the first voltage amplifier amplifies one of the first and the second analog gray level signal for N times.

4. The driving apparatus as claimed in claim 1, wherein the first voltage amplifier comprises:
a first amplifier, having a first input terminal, a second input terminal and an output terminal, wherein the first input terminal receives one of the first and the second analog gray level signal;
a first transistor, having a gate, a first source/drain and a second source/drain, wherein the gate is coupled to the output terminal of the first amplifier, and the first source/drain is coupled to the second voltage;
a second transistor, having a gate, a first source/drain and a second source/drain, wherein the gate is coupled to the output terminal of the first amplifier, the first source/drain is coupled to the second source/drain of the first transistor, and the second source/drain is coupled to a ground voltage;
a first voltage-dividing impedance device, having one terminal coupled to the second source/drain of the first transistor, and another terminal thereof coupled to the second input terminal of the first amplifier; and
a second voltage-dividing impedance device, coupled in serial between the first voltage-dividing impedance device and the ground voltage.

5. The driving apparatus as claimed in claim 4, wherein the first transistor is a P channel metal oxide semiconductor field effect transistor (PMOSFET).

6. The driving apparatus as claimed in claim 4, wherein the second transistor is a N channel metal oxide semiconductor field effect transistor (NMOSFET).

7. The driving apparatus as claimed in claim 1 further comprising:
an interleaver, coupled between coupling paths between the first and the second digital to analog converter and the first voltage amplifier; and
a second voltage amplifier, coupled to the interleaver, for receiving and amplifying one of the first and the second analog gray level signal,
wherein the interleaver transmits the digital positive polarity gamma voltage to one of the first voltage amplifier and the second voltage amplifier, and transmits the digital negative polarity gamma voltage to another one of the first voltage amplifier and the second voltage amplifier according to a polarity control signal.

8. The driving apparatus as claimed in claim 7, wherein the second voltage amplifier comprises:
a second amplifier, having a first input terminal, a second input terminal and an output terminal, wherein the first input terminal receives one of the first and the second analog gray level signal;
a third transistor, having a gate, a first source/drain and a second source/drain, wherein the gate is coupled to the output terminal of the second amplifier, and the first source/drain is coupled to the second voltage;
a fourth transistor, having a gate, a first source/drain and a second source/drain, wherein the gate is coupled to the output terminal of the second amplifier, the first source/drain is coupled to the second source/drain of the third transistor, and the second source/drain is coupled to the ground voltage;
a third voltage-dividing impedance device, having one terminal coupled to the second source/drain of the third transistor, and another terminal coupled to the second input terminal of the second amplifier; and
a fourth voltage-dividing impedance device, coupled in serial between the third voltage-dividing impedance device and the ground voltage.

9. The driving apparatus as claimed in claim 7, wherein the third transistor is a PMOS.

10. The driving apparatus as claimed in claim 7, wherein the fourth transistor is a NMOS.

11. The driving apparatus as claimed in claim 1 further comprising:
a first data storage device, coupled to the first digital to analog converter, for providing the first gray level signal; and
a second data storage device, coupled to the second digital to analog converter, for providing the second gray level signal.

12. The driving apparatus as claimed in claim 11, wherein the first and the second data storage device are latches or flip-flops.

13. The driving apparatus as claimed in claim 1, wherein the voltage divider comprises:
a plurality of impedance devices coupled in serial between the first voltage and the ground voltage.

14. The driving apparatus as claimed in claim 1, wherein the impedance devices are resistors.

15. The driving apparatus as claimed in claim 14, wherein the resistors are formed by N channel/P channel wells or a polysilicon layer.
